(19) United States
(12) Patent Application Publication
(10) Pub. No.: US 2012/0322204 A1
(43) Pub. Date: Dec. 20, 2012

(54) SEMICONDUCTOR ELEMENT AND METHOD OF MANUFACTURING THE SAME

(75) Inventor: Yoichiro KURITA, Kanagawa (JP)

(73) Assignee: Renesas Electronics Corporation, Kanagawa (JP)

(21) Appl. No.: 13/595,416

(22) Filed: Aug. 27, 2012

Related U.S. Application Data
(63) Continuation of application No. 12/926,642, filed on Dec. 1, 2010.
Application No. 12/926,642 is a division of application No. 12/153,878, filed on May 27, 2008, now abandoned.

(30) Foreign Application Priority Data
May 28, 2007 (JP) 139971/2007

(51) Int. Cl. H01L 21/50; H01L 21/283

(52) U.S. Cl. 438/107; 438/613; 257/E21.158; 257/E21.499

(57) ABSTRACT

A method of manufacturing a semiconductor device includes preparing a semiconductor element including a main surface over which a wiring layer is formed, forming a seed layer over the main surface, forming a resist layer over the main surface such that the resist layer covers the seed layer, removing a part of the resist layer by exposing and developing the resist layer, in which a part of the wiring layer is exposed from the removed part of the resist layer, forming a plurality of conductive posts electrically connected to the wiring layer at the removed part of the resist layer, forming a solder layer at each top of the plurality of conductive posts, removing a residual resist layer over the main surface, removing an area other than an area which overlaps with the seed layer, and melting the solder layer and forming a surface shape.

The present application is a Continuation Application of U.S. patent application Ser. No. 12/926,642, filed on Dec. 1, 2010, which is a Divisional Application of U.S. patent application Ser. No. 12/153,878, filed on May 27, 2008, which is based on and claims priority from Japanese patent application No. 2007-139971, filed on May 28, 2007, the entire contents of which are incorporated herein by reference.

### BACKGROUND OF THE INVENTION

1. Field of the Invention

The present invention relates to a semiconductor element and a method of manufacturing a semiconductor element.

2. Description of the Related Art

Conventionally, a three-dimensional mounting technology involving stacking semiconductor elements has been proposed along with the miniaturization and high-density mounting of semiconductor devices.

A semiconductor element used for the three-dimensional mounting technology includes a conductive post portion protruding from the surface of a semiconductor substrate (for example, see JP 2002-280407 A).

In JP 2002-280407 A, when a semiconductor element is three-dimensionally mounted, a molten solder is disposed between the conductive post portion (first metal layer) and a bonding portion (for example, electrode) formed on a semiconductor substrate of another semiconductor element, and then the conductive post portion and the bonding portion formed on the semiconductor substrate of the another semiconductor element are bonded.

However, when such a semiconductor element is three-dimensionally mounted, the molten solder may flow out from between the conductive post portion and the bonding portion. In some cases, the molten solder which is flowing out may come into contact with an adjacent conductive post portion, thereby causing a short circuit. Moreover, the contact of the molten solder with an insulating layer of the surface of the semiconductor element may also cause the generation of an electrical parasitic capacitance.

In order to solve the problems, there is proposed a method involving arranging a gap material for holding a predetermined interval formed between semiconductor elements to be stacked (see JP 2005-123601 A).

There is also proposed a method involving forming a projecting portion protruding higher than a post electrode on the surface near the post electrode of a semiconductor element (see JP 2005-150299 A).

In addition, as shown in FIG. 7, there is proposed a method involving forming, on a semiconductor element body 101 made of silicon of a semiconductor element 100, a columnar first terminal 102 protruding from the semiconductor element body 101, and, on the first terminal 102, a mushroom-like second terminal 103 (see JP 2005-347678 A).

Note that, in JP 2005-347678 A, there is a description that the mushroom-like second terminal 103 is formed so as to protrude from the semiconductor element body 101 as shown in FIG. 8.

The present inventor has recognized that the conventional technologies have the following problems.

In JP 2005-123601 A and JP 2005-150299 A, the gap material and the projecting portion are provided, which increases the number of materials and also requires production processes for providing the gap material and the projecting portion. As a result, the production processes become complicated and sufficient production stability cannot be obtained.

In JP 2005-347678 A, the semiconductor element 100 includes the second terminal 103. The second terminal 103 has a mushroom-like shape and has a recessed portion 103A recessed in a direction substantially orthogonal to a protruding direction of the second terminal 103. Consequently, the strength of the second terminal 103 is liable to be weak and the semiconductor element of JP 2005-347678 A has an insufficient production stability.

Further, in the case where the second terminal 103 is provided on the columnar first terminal 102 protruding from the semiconductor element body 101, the structure becomes complicated and the production stability of the semiconductor element becomes more insufficient.

### SUMMARY

According to an aspect of the present invention, there is provided a semiconductor element including: a semiconductor substrate; and a conductive post portion protruding from the semiconductor substrate, in which the conductive post portion has a distal end surface curved in a substantially arc shape, and is free from a recessed portion recessed in a direction intersecting with a protruding direction of the conductive post portion on an outer surface extending from a distal end to a proximal end on a semiconductor substrate side.

In this case, it is sufficient if the conductive post portion be free from the recessed portion which is recessed in the direction intersecting with the protruding direction of the conductive post portion on the outer surface extending from the distal end to the proximal end thereof. For example, the conductive post portion may be formed in a substantially hemispherical shape. Moreover, in the case where the conductive post portion includes a first portion having the distal end surface which is curved in an arc shape and a second portion extending from a periphery of the distal end surface of the first portion to the semiconductor substrate side, the second portion may be formed in a non-curved shape. Alternatively, the second portion may be formed in a tapered shape or reverse tapered shape so that the side surface of the second portion may be inclined against the surface of the semiconductor substrate at a substantially constant angle.

According to the present invention, the conductive post portion has the distal end surface which is curved in a substantially arc shape. Accordingly, when the semiconductor element of the present invention and another semiconductor element or a substrate are connected with each other, a distance between a peripheral portion of the distal end surface of the conductive post portion and a bonding portion provided to the another semiconductor element or the substrate becomes wider.

In the case where the semiconductor element of the present invention is connected with the another semiconductor element or the substrate, the conductive post portion is connected with the bonding portion of the another semiconductor element or the like through molten solder. The molten solder can be accommodated in a space defined between the bonding portion and the peripheral portion of the distal end surface of the conductive post portion. This prevents the molten solder from flowing out up to the side of the bonding portion.

In addition, such a semiconductor element of the present invention has an excellent production stability.

Specifically, as described above, the present invention allows the molten solder to be accommodated in the space defined between a bonding portion of another semiconductor element or the like and the peripheral portion of the distal end surface of the conductive post portion. As a result, the gap materials and the projecting portions, which have been conventionally employed, are unnecessary. Therefore, the number of materials for a semiconductor element is prevented from increasing, and further the production processes can be simple, thereby obtaining a semiconductor element having an excellent production stability.

In the semiconductor element 100 shown in FIG. 7, the recessed portion 103A is formed on the outer surface extending from the distal end of the second terminal 103 to the proximal end of the first terminal 102.

Also in the semiconductor element shown in FIG. 8, the recessed portion 103A is formed on the outer surface extending from the distal end of the second terminal 103 to the proximal end of the first terminal 102.

In the case where the recessed portion is formed as described above, the strength of the terminal is liable to be weak, and thus the semiconductor element of JP 2005-347678 A has an insufficient production stability.

In contrast, the semiconductor element of the present invention is not formed with the recessed portion which is recessed in the direction intersecting with the protruding direction of the conductive post portion on the outer surface extending from the distal end to the proximal end on the semiconductor substrate side. Accordingly, the strength of the conductive post portion can be ensured, and thus the semiconductor element has an excellent production stability.

In addition, these days there are demands for miniaturization of conductive post portions in semiconductor elements. In the case where the shape of the conductive post portion in which the recessed portion is not formed is employed as in the present invention, the strength of the conductive post portion can be ensured, thereby facilitating the miniaturization thereof.

According to another aspect of the present invention, there is provided a semiconductor element including: a semiconductor substrate; and a conductive post portion protruding from the semiconductor substrate, in which: the conductive post portion has a distal end surface and is provided to the semiconductor substrate so that the distal end surface is curved in a substantially arc shape; the conductive post portion is provided thereon with a solder layer covering the distal end surface; and the solder layer at a top of the distal end surface is thicker than the solder layer at other portion.

When the conductive post portion and an electrode formed on a substrate (or another semiconductor element) on which the former semiconductor element is mounted are bonded, making the solder layer gradually increased in thickness from the peripheral portion of the distal end surface of the conductive post portion toward the top of the distal end surface of the conductive post portion allows the solder to be reliably prevented from flowing out from the peripheral portion of the distal end surface of the conductive post portion toward the side of the conductive post portion, even in the case where the solder existing at the top of the conductive post portion flows out toward the peripheral portion side of the distal end surface of the conductive post portion.

The semiconductor element described above can be manufactured by the following method.

Specifically, according to still another aspect of the present invention, there is provided a method of manufacturing a semiconductor element including: a semiconductor substrate; a conductive post portion protruding from the semiconductor substrate; and a solder layer provided on the conductive post portion, the method including the steps of: forming on the semiconductor substrate the conductive post portion having a distal end surface curved in a substantially arc shape by electrolytic plating; forming the solder layer on the distal end surface of the conductive post portion; and reflowing the solder layer to form the solder layer which has the thickest portion at a top of the distal end surface of the conductive post portion.

According to the present invention, there are provided a semiconductor element which can be bonded satisfactorily with another semiconductor element or a substrate and has an excellent production stability, and a method of manufacturing a semiconductor element.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view showing a semiconductor element according to an embodiment of the present invention;

FIGS. 2A to 2D are sectional views showing production processes of a semiconductor element;

FIGS. 3A to 3D are sectional views showing production processes of the semiconductor element;

FIG. 4 is a sectional view showing a state in which semiconductor elements are stacked;

FIG. 5 is a sectional view showing a semiconductor element according to a modification of the present invention;

FIG. 6 is a sectional view showing a state in which semiconductor elements are stacked;

FIG. 7 is a sectional view showing a semiconductor element of a conventional technology; and

FIG. 8 is a schematic view showing a semiconductor element of the conventional technology.

### DETAILED DESCRIPTION OF THE PREFERRED EMBODIMENT

Hereinafter, an embodiment of the present invention will be described with reference to the drawings.

First, a description will be made of outlines of a semiconductor element 1 of this embodiment.

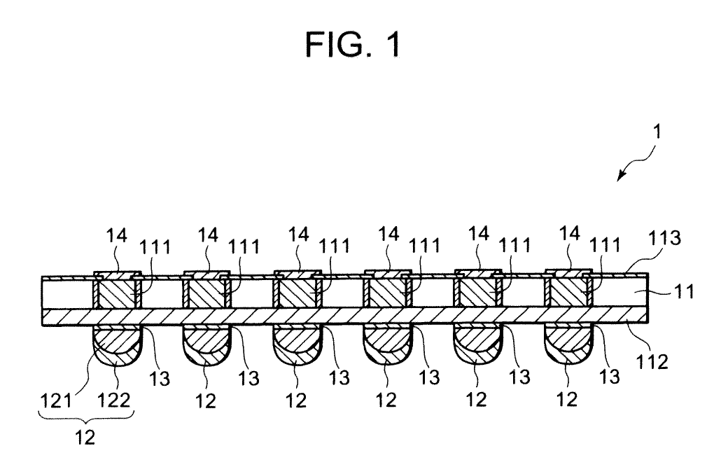

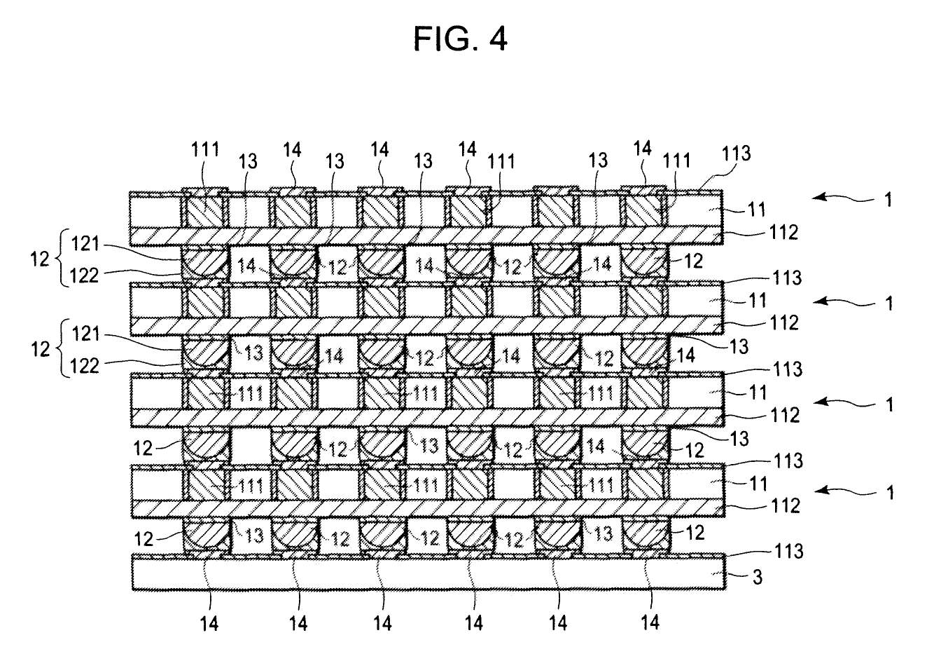

As shown in FIGS. 1 and 4, the semiconductor element 1 of this embodiment includes a semiconductor substrate 11 and a conductive post portion 121 protruding from the semiconductor substrate 11.

The conductive post portion 121 is provided to the semiconductor substrate 11 without forming, on the outer surface extending from the distal end to the proximal end on the semiconductor substrate 11 side, a recessed portion which is recessed in a direction intersecting with a protruding direction of the conductive post portion 121.

Further, a distal end surface of the conductive post portion 121 is curved in a substantially arc shape.

Next, a detailed description will made of the semiconductor element 1. As shown in FIG. 1, the semiconductor element 1 includes the semiconductor substrate 11 and a post 12 provided on the semiconductor substrate

On the semiconductor substrate 11, there are formed multiple conductive through-hole portions (through-hole electrodes) 111 passing through the semiconductor substrate 11. The multiple through-hole electrodes 111 are arranged at predetermined pitches.

Each of the through-hole electrode 111 includes conductors such as copper, tungsten, and polysilicon, and may include materials different from those of the conductive post portion 121.

A wiring layer 112 (layer including wiring and an insulating layer) is formed on one surface of the semiconductor substrate 11.

An insulating layer 113 is formed on the other surface of the semiconductor substrate 11 on which the wiring layer 112 is not formed. The insulating layer 113 is provided with an opening and an electrode 14 which is arranged so as to bury the opening therein.

There are provided multiple electrodes 14, each of which is connected with each of the through-hole electrodes 111.

There are multiple posts 12 which are arranged on the semiconductor substrate 11, each of which is connected with each of the through-hole electrodes 111 via the wiring layer 112.

The post 12 is used for connection between the semiconductor element 1, and another semiconductor element 1, a substrate 3, or the like (see FIG. 4).

The post 12 includes the conductive post portion 121 and a solder layer 122.

The conductive post portion 121 is mounted on the semiconductor substrate 11 so as to protrude therefrom. The conductive post portion 121 is a bonding portion which is bonded by the solder of the solder layer 122 when bonding the semiconductor element 1 to another semiconductor element 1 or the like.

The conductive post portion 121 is curved over the entire surface with the distal end surface thereof forming an arc shape. The conductive post portion 121 is provided to the semiconductor substrate 11 without forming, on the outer surface extending from the distal end to the proximal end on the semiconductor substrate 11 side, a recessed portion which is recessed in a direction intersecting with a protruding direction of the conductive post portion 121.

Further, the conductive post portion 121 does not include an eaves portion projecting in a direction substantially parallel to the substrate surface of the semiconductor substrate 11.

In this embodiment, in a cross section of the conductive post portion 121 orthogonally intersecting with the substrate surface of the semiconductor substrate 11, the outline thereof extends from the distal end to the proximal end without having an inflection point.

Also, in this embodiment, the conductive post portion 121 protrudes from the semiconductor substrate 11 without forming a constriction therein.

In this embodiment, the distal end surface of the conductive post portion 121 corresponds to the entire surface facing a bonding portion (electrode 14) of another semiconductor element 1 or the like when the semiconductor element 1 is bonded to another semiconductor element 1 or the like.

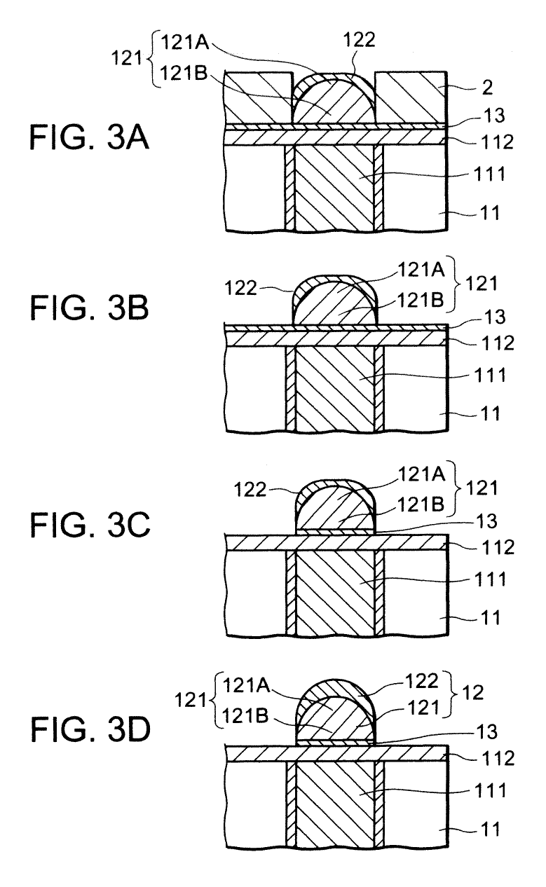

The conductive post portion 121 includes a first portion 12IA having the distal end surface and a second portion 121 B extending from the periphery of the distal end surface of the first portion 121A toward the semiconductor substrate 11 side in a columnar shape. (See FIG. 3D.)

The first portion 121A is curved over the entire surface so as to assume an arc whose top is approximately at the center of the distal end surface of the first portion 121A, that is, so as to have a substantially arc shape. In this embodiment, the distal end surface of the first portion 121A has a substantially spherical shape.

The first portion 121A is connected with the semiconductor substrate 11 through the periphery of the distal end surface. Specifically, in this embodiment, the first portion 121A is connected with the semiconductor substrate 11 through the periphery of the distal end surface, that is, the second portion 121B extending from the periphery of the distal end surface toward the semiconductor substrate side.

The second portion 121B has a cross section having a substantially rectangular shape which orthogonally intersects with the substrate surface of the semiconductor substrate 111. In this embodiment, the second portion 121B has a substantially columnar shape.

In this embodiment, the second portion 121B has a cross section having a substantially rectangular shape, but the shape of second portion 121B is not limited thereto. The second portion 121B may have a reverse tapered shape gradually increased in diameter or a tapered shape gradually reduced in diameter from the proximal end on the semiconductor element 111 side toward the distal end of the first portion 121A.

A width dimension of the proximal end of the second portion 121B in a direction along the substrate surface of the semiconductor substrate 11 is the same as that of the through-hole electrode 111 in the direction along the substrate surface of the semiconductor substrate 11. Alternatively, the width dimension of the proximal end of the second portion 121B is larger than that of the through-hole electrode 111.

The conductive post portion 121 as described above includes a conductive material having a higher melting point than that of the solder layer 122, such as a metal material. For example, the conductive post portion 121 includes copper or nickel.

The solder layer 122 covers the distal end surface of the conductive post portion 121. In this embodiment, the solder layer 122 covers the entire distal end surface of the conductive post portion 121.

The solder layer 122 is formed along the distal end surface of the conductive post portion 121 and formed with the surface curved in a substantially arc shape.

The solder layer 122 is thickest at the top of the conductive post portion 121 and becomes thicker from the periphery of the distal end surface of the conductive post portion 121 toward the top of the distal end surface thereof.

As a material of the solder layer 122, a Pb-free solder such as Sn—Ag based solder, Sn—Bi based solder, or Sn—Zn based solder may be used. As the solder layer 122, a solder containing Pb such as Sn/95Pb or Sn/63Pb may be used.

Multiple number of the posts 12 as described above are provided on a seed layer 13 formed on the wiring layer 112 of the semiconductor substrate 11 so as to cover the entire surface of the seed layer 13.

The seed layer 13 is directly formed on the wiring layer 112 of the semiconductor substrate 11. A width dimension of the seed layer 13 is equal to or larger than that of the through-hole electrode 111 of the semiconductor substrate 11.

Examples of the seed layer 13 include a layer containing a metal such as Cu or Ti.

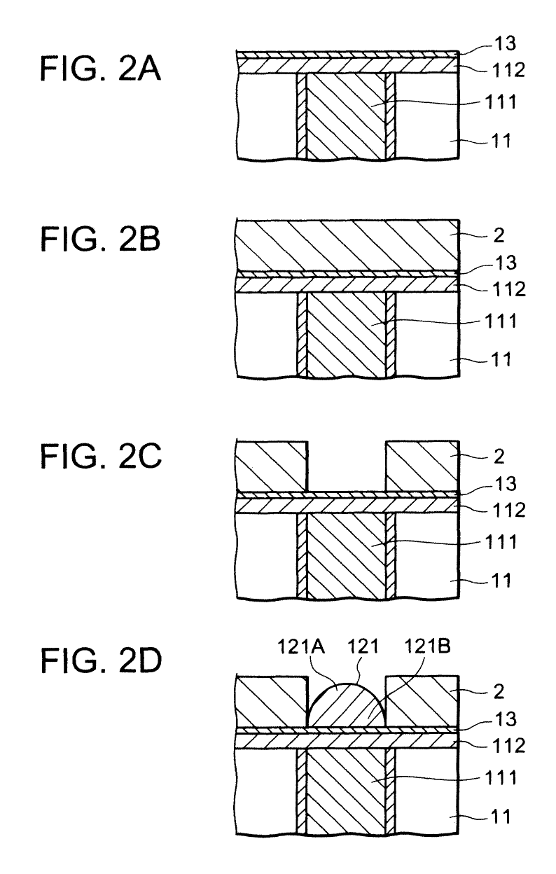

Next, a description will be made of a method of manufacturing the above semiconductor element 1 with reference to FIGS. 2 and 3.

The method of manufacturing the semiconductor element 1 includes the steps of: forming on the semiconductor substrate 11 the conductive post portion 121 which has a distal end surface curved in a substantially arc shape and is free from a recessed portion which is recessed in a direction intersecting with a protruding direction of the conductive post portion 121 on the outer surface extending from the distal end to the proximal end on the semiconductor substrate 11 side by electrolytic plating; forming the solder layer 122 on the distal end surface of the conductive post portion 121; and reflowing the solder layer 122 to form the solder layer 122 which has the thickest portion at the top of the distal end surface of the conductive post portion 121.

Details of the method will be described below.

As shown in FIG. 2A, the seed layer 13 covering the wiring layer 112 located on the surface of the semiconductor substrate 11 is formed by sputtering.

Next, as shown in FIG. 2B, a photoresist 2 is applied so as to cover the seed layer 13. The photoresist 2 is then exposed and developed to selectively remove the photoresist 2 as shown in FIG. 2C. Specifically, the photoresist 2 arranged at a position corresponding to that of the through-hole electrode 111 is removed.

Then, the conductive post portion 121 is formed (FIG. 2D). The conductive post portion 121 is formed by electrolytic plating. Specifically, the electrolytic plating is performed by immersing the semiconductor substrate 11 on which the photoresist 2 is formed in a plating solution containing a metal such as Cu or Ni, constituting the conductive post portion 121. In this case, various additives are appropriately added in the plating solution. For example, polyethylene glycol is added as the additive.

The conductive post portion 121 formed as described above is curved so as to assume an arc whose top is approximately at the center of the distal end surface thereof. In this embodiment, the distal end surface is curved in a substantially arc shape.

Subsequently, a solder constituting the solder layer 122 is plated on the conductive post portion 121 (FIG. 3A). The thickness of the solder on the conductive post portion 121 is substantially uniform in this example.

Next, the photoresist 2 is removed as shown FIG. 3B.

Then, as shown in FIG. 3C, the seed layer 13 is selectively removed. Specifically, an exposed part of the seed layer 13 on which the conductive post portion 121 is not formed is removed by etching.

As shown in FIG. 3D, the semiconductor substrate 11 and the post 12 are subjected to heat treatment and reflow is performed under predetermined conditions. Various conditions for reflow are appropriately adjusted and therefore the surface of the solder layer 122 is curved in a substantially arc shape and the top of the conductive post portion 121 has the largest thickness. Further, the solder layer 122 is gradually increased in thickness from the periphery of the distal end surface of the conductive post portion 121 toward the top of the distal end surface thereof.

Through the above steps, the semiconductor element 1 can be obtained.

The semiconductor element 1 thus obtained is three-dimensionally stacked as shown in FIG. 4 to constitute a semiconductor device.

Specifically, the solder layer 122 of the post 12 provided to the semiconductor element 1 is molten to bond an electrode 14 of another semiconductor element 1 or the substrate 3 therewith, applied with pressure, and stacked.

The substrate 3 is provided on the surface thereof with the insulating layer 113 and he electrode 14 is provided to an opening of the insulating layer 113.

Effects of the present invention will be described below.

The semiconductor element 1 protrudes from the semiconductor substrate 11 and includes the conductive post portion 121 having a distal end surface curved in a substantially arc shape. Accordingly, when the semiconductor element 1 is stacked on the substrate 3 or another semiconductor element 1, a distance between the semiconductor element 1 and the substrate 3 or a distance between the electrode 14 of another semiconductor element 1 and the peripheral portion of the distal end surface of the conductive post portion 121 becomes wider.

When the post 12 of the semiconductor element 1 and the electrode 14 of another semiconductor element 1 or the substrate 3 are bonded with each other, the solder layer 122 is molten to perform bonding, in which the molten solder can be accommodated in a space defined between the electrode 14 and the peripheral portion of the distal end surface of the conductive post portion 121.

Therefore, the molten solder layer 122 can be prevented from flowing out toward the adjacent post 12 or from being attached to the insulating layer 113.

The above-mentioned shape of the conductive post portion 121 can suppress flowing out of the molten solder layer 122, so the gap materials and projecting portions conventionally employed are unnecessary. Therefore, the number of materials for the semiconductor element 1 is prevented from increasing and further the production processes can be simple, thereby obtaining the semiconductor element 1 having an excellent production stability.

Further, in the case of providing the gap materials or projecting portions as in the conventional technologies, the gap materials or projecting portions may inhibit flow of a resin when the semiconductor element 1 is stacked and then sealed by the resin, whereby a void may occur in the resin.

On the other hand, this embodiment does not require the gap materials or projecting portions, thereby preventing occurrence of the void in the resin when the semiconductor element 1 is sealed by the resin.

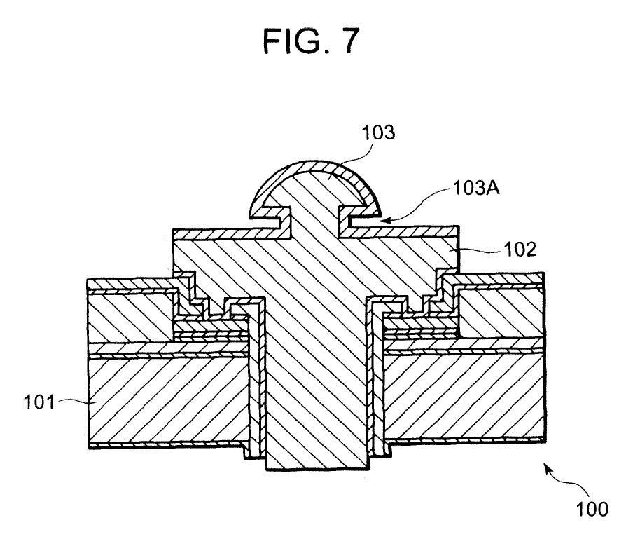

In a conventional semiconductor element shown in FIG. 7, a recessed portion 103A is formed on the outer surface extending from a distal end of a second terminal 103 to a proximal end of a first terminal 102.

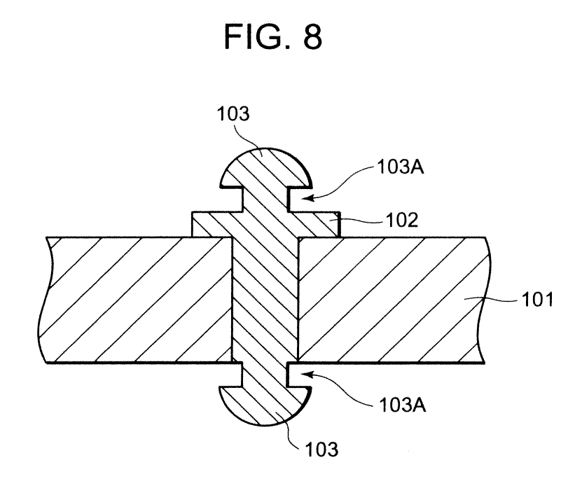

Also in a semiconductor element shown in FIG. 8, the recessed portion 103A is formed on the outer surface extending from the distal end of the second terminal 103 to the proximal end of the first terminal 102.

In the case where the recessed portion is formed as described above, the strength of the terminal is liable to be weak and the semiconductor element of JP 2005-347678 A has an insufficient production stability.

In contrast, the semiconductor element 1 of the present invention is not formed with the recessed portion which is recessed in the direction intersecting with a protruding direction of the conductive post portion 121 on the outer surface extending from the distal end to the proximal end on the semiconductor substrate 11 side. Accordingly, the strength of the conductive post portion 121 can be ensured and thus the semiconductor element 1 has an excellent production stability.

In addition, these days there are demands for miniaturization of conductive post portions in semiconductor elements. In the case where the shape of the conductive post portion 121 in which the recessed portion is not formed is employed as in this embodiment, the strength of the conductive post portion 121 can be ensured, thereby facilitating the miniaturization thereof.

Further, in this embodiment, the conductive post portion 121 does not include an eaves portion projecting in a direction substantially parallel to the substrate surface of the semiconductor substrate 11, which leads to a simpler shape of the conductive post portion 121.

Also, the width dimension of the proximal end of the conductive post portion 121 in a direction along the substrate surface of the semiconductor substrate 11 is equal to or larger than that of the through-hole electrode 111 in the direction along the substrate surface of the semiconductor substrate 11. Therefore, compared with the semiconductor element shown in FIG. 8, the conductive post portion 121 can be firmly fixed to the semiconductor substrate 11.

In this embodiment, the solder layer 122 is thickest at the top of the distal end surface of the conductive post portion 121. That is, the solder layer 122 is thinner in a region excluding the top of the distal end surface of the conductive post portion 121 than the top of the distal end surface of the conductive post portion 121. Therefore, when the semiconductor element 1 and another semiconductor element 1 or the like are bonded with each other, flowing out of the solder toward the side of the conductive post portion 121 can be suppressed.

In particular, when the post 12 and the electrode 14 are bonded to each other, making the solder layer 122 gradually increased in thickness from the peripheral portion of the distal end surface of the conductive post portion 121 toward the top thereof allows the solder to be reliably prevented from flowing out from the peripheral portion of the distal end surface of the conductive post portion 121 toward the side of the conductive post portion 121, even in the case where the solder existing on the top of the conductive post portion 121 flows out toward the peripheral portion side of the distal end surface of the conductive post portion 121.

In the case where the semiconductor element 1 is preserved for a long period of time, the metal constituting the conductive post portion 121 may be diffused to the solder layer 122. Due to the diffusion of the metal constituting the conductive post portion 121, the surface composition of the solder layer 122 may be changed. However, the solder layer 122 is thickest at the top of the conductive post portion 121, so a change of the surface composition of the solder layer 122 can be suppressed at the top of the conductive post portion 121.

In this embodiment, the conductive post portion 121 includes a metal containing Cu, Ni, or the like, so melting of the conductive post portion 121 can be reliably prevented when the solder layer 122 is molten.

In this embodiment, the conductive post portion 121 is formed by electrolytic plating. By appropriately adjusting the additives of the plating solution, the conductive post portion 121 can be curved over the entire surface with the distal end surface thereof in a substantially arc shape. That is, by appropriately adjusting the additives of the plating solution, the conductive post portion 121 can be formed easily.

Note that the present invention is not limited to the above-mentioned embodiment and includes modification, improvement, and the like in the range in which an object of the present invention can be achieved.

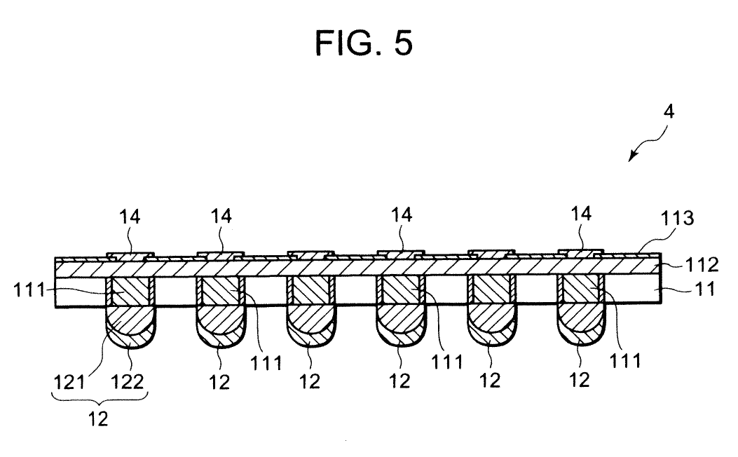

For example, in the above embodiment, the post 12 of the semiconductor element 1 is formed on the wiring layer 112, but the position of the post 12 is not limited thereto. For example, the post 12 may be directly formed on the other surface of the semiconductor substrate 11 on which the wiring layer 112 is not formed as in the case of a semiconductor element 4 shown in FIG. 5.

In the semiconductor element 4, the insulating layer 113 is formed on the wiring layer 112. The electrode 14 is provided to an opening formed on the insulating layer 113 and is connected with the wiring layer 112.

Other components of the semiconductor element 4 are the same as those of the semiconductor element 1 of the above embodiment.

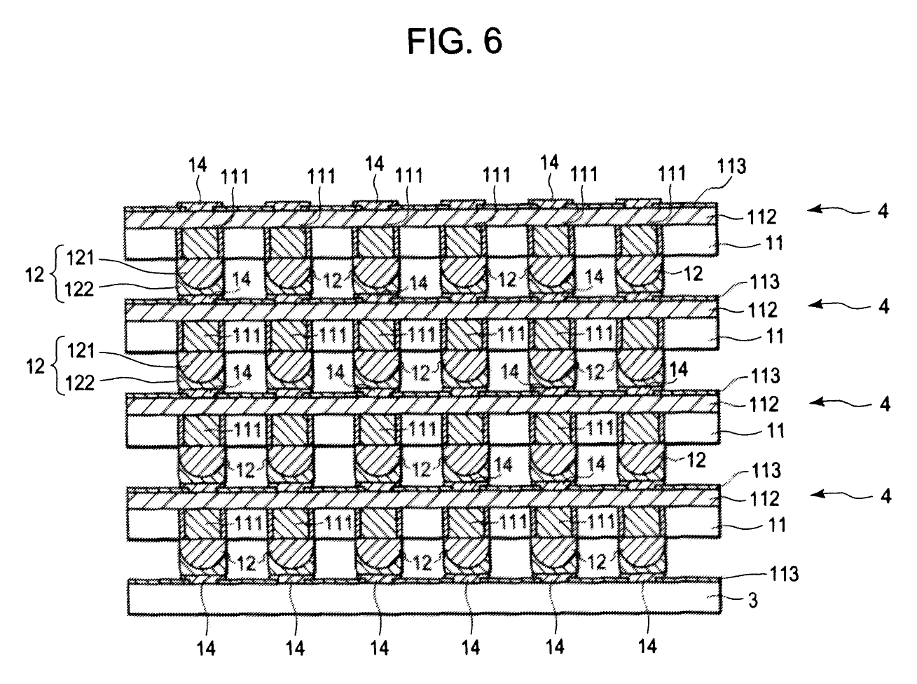

The semiconductor element 4 as described above is stacked as shown in FIG. 6.

In the semiconductor element 4 as shown in FIGS. 5 and 6, the same effects as in the embodiment can be achieved.

Note that, in semiconductor element 4, the conductive post portion 121 of the post 12 may be integrated with the through-hole electrode 111.

Further, in the embodiment, the solder layer 122 is thickest at the top of the conductive post portion 121, but the thickness of the solder layer 122 is not limited thereto and may be uniform.

Also, in the embodiment, the conductive post portion 121 includes copper or nickel, but the components of the conductive post portion 121 are not limited thereto and may include other metals.

However, in the case where the conductive post portion 121 includes copper or nickel as in the embodiment, the conductive post portion 121 can be easily formed by electrolytic plating. That is, by adjusting the additives in the plating solution, the distal end surface of the conductive post portion 121 is curved in a substantially arc shape by electrolytic plating. Therefore, the conductive post portion 121 having the distal end surface can be easily formed.

Although the present invention has been described above in connection with several preferred embodiments thereof, it is apparent that the present invention is not limited to above embodiments, but may be modified and changed without departing from the scope and spirit of the invention.

What is claimed is:

1. A method of manufacturing a semiconductor device, said method comprising;
preparing a semiconductor element comprising a main surface over which a wiring layer is formed;
forming a seed layer over the main surface of the semiconductor element such that the seed layer covers the wiring layer;
forming a resist layer over the main surface of the semiconductor element such that the resist layer covers the seed layer;
removing a part of the resist layer by exposing and developing the resist layer, in which a part of the wiring layer is exposed from the removed part of the resist layer;
forming a plurality of conductive posts electrically connected to the wiring layer at the removed part of the resist layer;
forming a solder layer at each top of the plurality of conductive posts;
removing a residual resist layer over the main surface of the semiconductor element;
removing an area other than an area which overlaps with the seed layer in a plan view; and
after said removing the area, melting the solder layer and forming a surface shape thereof by heating the semiconductor element.

2. The method of manufacturing a semiconductor device according to claim 1, wherein the solder layer includes Sn.

3. The method of manufacturing a semiconductor device according to claim 2, wherein the seed layer includes Cu.

4. The method of manufacturing a semiconductor device according to claim 3, wherein the seed layer includes Ti.

5. The method of manufacturing a semiconductor device according to claim 1, wherein, in said melting the solder layer and said forming the surface shape, the solder layer is melted such that the surface shape of the solder layer becomes substantially an arc shape.

6. The method of manufacturing a semiconductor device according to claim 1, wherein, in said melting the solder layer and said forming the surface shape, the solder layer is melted such that the surface shape of the solder layer draws an arc and a substantial center part of the solder layer becomes a top part of the arc.

7. The method of manufacturing a semiconductor device according to claim 1, wherein, in said melting the solder layer and said forming the surface shape, the solder layer is melted such that a thickness of the solder layer increases from a peripheral part toward a top part of the solder layer.

8. The method of manufacturing a semiconductor device according to claim 1, wherein a conductive port of the conductive posts comprises a first portion and a second portion between the first portion and the wiring layer in a thickness direction of the semiconductor element, and
wherein, in said forming the plurality of conductive posts, the conductive post is formed such that a shape of the second portion of the conductive post becomes substantially a columnar shape.

9. The method of manufacturing a semiconductor device according to claim 8, wherein, in said forming the plurality of conductive posts, the conductive post is formed such that a shape of the first portion of the conductive post becomes substantially a spherical shape.

10. The method of manufacturing a semiconductor device according to claim 1, wherein, in said forming the plurality of conductive posts, a conductive port of the conductive posts is formed by an electrolytic plating.

11. The method of manufacturing a semiconductor device according to claim 1, wherein a melting point of each of the plurality of conductive posts is more than a melting point of the solder layer.

12. The method of manufacturing a semiconductor device according to claim 1, wherein each of the plurality of conductive posts comprises Cu.

13. The method of manufacturing a semiconductor device according to claim 12, wherein each of the plurality of conductive posts further comprises Ni.

14. The method of manufacturing a semiconductor device according to claim 1, wherein the seed layer is formed by sputtering.

15. The method of manufacturing a semiconductor device according to claim 1, wherein, in said forming a solder layer, the solder layer is formed such that a thickness of the solder layer becomes even over each of the plurality of conductive posts.

16. The method of manufacturing a semiconductor device according to claim 1, wherein, after said melting the solder layer and said forming the surface shape, the semiconductor element is mounted over a substrate provided with a plurality of electrodes, and
wherein the plurality of electrodes of the substrate are electrically connected to the plurality of conductive posts of the semiconductor element via the solder layer, respectively.

17. The method of manufacturing a semiconductor device according to claim 1, wherein, after said melting the solder layer and said forming the surface shape, the semiconductor element is mounted over another semiconductor element provided with a plurality of electrodes, and
wherein the plurality of electrodes of said another semiconductor element is electrically connected to the plurality of conductive posts of the semiconductor element via the solder layer, respectively.
